(19) United States
(12) Patent Application Publication
(10) Pub. No.: US 2024/0162381 A1
(43) Pub. Date: May 16, 2024

(54) SHAPED COVER STRUCTURES WITH LUMIPHORIC MATERIALS FOR LIGHT-EMITTING DIODE PACKAGES AND RELATED METHODS

(71) Applicant: CreeLED, Inc., Durham, NC (US)

(72) Inventors: David Suich, Durham, NC (US); Robert Wilcox, Rolesville, NC (US); Michael Check, Holly Springs, NC (US); Andre Pertuit, Raleigh, NC (US); Colin Blakely, Raleigh, NC (US)

(21) Appl. No.: 17/984,875

(22) Filed: Nov. 10, 2022

(51) Int. Cl. H01L 33/20; H01L 33/00; H01L 33/50

(52) U.S. Cl. CPC H01L 33/20; H01L 33/005; H01L 33/502; H01L 2933/0041

(57) ABSTRACT

The present disclosure relates to techniques for providing and fabricating a 3D shaped cover structure for a light emitting diode (LED) package that has improved light emission efficiencies and color over angle emissions over flat cover structures. The cover structure can form a hemispherical dome over an LED chip, so that light incident on the inside surface of the dome will be at a more acute angle which can reduce the internal reflection of light emitted by the LED chip. The cover structure can also serve as a remote phosphor lumiphore, thereby improving color over angle emission and reduce the need for an additional adhesion interface on the LED. The cover structure can be shaped during a green sheet lamination and sintering process to create the 3D shape. In other embodiments, a structure can be machined into a desired shape.

### FIELD OF THE DISCLOSURE

The present disclosure relates to light-emitting diode (LED) packages and, more particularly, to using a 3D molded or shaped phosphor in glass cover structure to improve a performance of the LED package.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

Typically, it is desirable to operate LEDs at the highest light emission efficiency possible, which can be measured by the emission intensity in relation to the output power (i.e., in lumens per watt). A practical goal to enhance emission efficiency is to maximize extraction of light emitted by the active region in the direction of the desired transmission of light. Light extraction and external quantum efficiency of an LED can be limited by a number of factors, including internal reflection. According to the well-understood implications of Snell's law, photons reaching an interface between an LED surface and the surrounding environment or even an internal interface of the LED can be either refracted or internally reflected. If photons are internally reflected in a repeated manner, then such photons are eventually absorbed and never provide visible light that exits an LED.

It is often desirable to incorporate a phosphor into the light emitting device, to enhance the emitted radiation in a particular frequency band and/or to convert at least some of the radiation to another frequency band.

The phosphor can be embedded in a glass cover structure that is bonded to the LED chip or device and can both protect the LED chip/device while also providing an emitted light in a desired frequency band. The phosphor in glass is traditionally flat, however, which can lead to reduced efficiency and impaired color over angle emission due to light entering the phosphor in glass cover structure at high angles.

The art continues to seek improved LEDs and solid-state lighting devices having desirable illumination characteristics capable of overcoming challenges associated with conventional lighting devices.

### SUMMARY

The present disclosure relates to techniques for providing and fabricating a 3D shaped phosphor in glass cover structure for a light emitting diode (LED) package that has improved light emission efficiencies and color over angle emissions over flat phosphor in glass cover structures. The phosphor in glass cover structure can form a hemispherical dome over an LED chip, so that light incident on the inside surface of the dome will be at a more acute angle which can reduce the internal reflection of light emitted by the LED chip. The phosphor in glass can also serve as a remote phosphor lumiphore, thereby improving color over angle emission and reduce the need for an additional adhesion interface on the LED. The phosphor in glass cover structure can be molded or pressed during a green sheet lamination and sintering process to create the 3D shape. In other embodiments, a phosphor in glass structure can be machined into a desired shape.

In an embodiment, an LED package can include a submount, an LED chip on the submount, and a glass cover structure embedded with a lumiphoric material, wherein an internal surface of the glass cover structure is non-planar, and at least a portion of the glass cover structure is not in contact with the LED chip.

In an embodiment, a method of forming an LED package comprising a glass cover structure can include laminating a plurality of sublayers each embedded with a lumiphoric material. The method can also include pressing the plurality of sublayers into a mold, wherein the plurality of sublayers conform to a predefined shape. The method can also include sintering the sublayers to form a glass cover structure. The method can also include fixing the glass cover structure to the LED package, wherein the glass cover structure covers an LED chip on the LED package.

In another embodiment, a method of forming an LED package comprising a glass cover structure can include laminating a plurality of sublayers each embedded with a lumiphoric material. The method can also include sintering the sublayers to form a glass block. The method can also include machining the glass block to form a glass cover structure having a hemispherical dome shape. The method can also include fixing the glass cover structure to the LED package, wherein the glass cover structure covers an LED chip on the LED package.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates an exemplary embodiment of a light emitting diode (LED) package with a 3D shaped phosphor in glass cover structure according to one or more aspects of the present disclosure.

FIGS. 2A and 2B illustrate exemplary embodiments of how a 3D shaped phosphor in glass cover structure can be mounted to a LED package according to one or more aspects of the present disclosure.

FIG. 3 illustrates an exemplary embodiment of how a 3D shaped phosphor in glass cover structure can be mounted to a LED package according to one or more aspects of the present disclosure.

FIGS. 4A and 4B illustrate an exemplary embodiment of a technique for fabricating a phosphor in glass structure according to one or more aspects of the present disclosure.

FIGS. 5A, 5B, and 5C illustrate another exemplary embodiment of a

technique for fabricating a 3D shaped phosphor in glass cover structure according to one or more aspects of the present disclosure.

FIGS. 6A, 6B, 6C, and 6D illustrate another exemplary embodiment of a technique for fabricating a 3D shaped phosphor in glass cover structure according to one or more aspects of the present disclosure.

FIGS. 7A and 7B illustrate another exemplary embodiment of a technique for fabricating a 3D shaped phosphor in glass cover structure according to one or more aspects of the present disclosure.

FIGS. 8A and 8B illustrate another exemplary embodiment of a technique for fabricating a 3D shaped phosphor in glass cover structure according to one or more aspects of the present disclosure.

FIG. 9 illustrates an exemplary flowchart of a method for fabricating a 3D shaped phosphor in glass cover structure according to one or more aspects of the present disclosure.

FIG. 10 illustrates another exemplary flowchart of a method for fabricating a 3D shaped phosphor in glass cover structure according to one or more aspects of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently redescribed.

The present disclosure relates to techniques for providing and fabricating a 3D shaped phosphor in glass (PiG) cover structure for a light emitting diode (LED) package that has improved light emission efficiencies and color over angle emissions over flat PiG cover structures. The PiG cover structure can form a hemispherical dome over an LED chip, so that light incident on the inside surface of the dome will be at a more acute angle which can reduce the internal reflection of light emitted by the LED chip. The PiG can also serve as a remote phosphor lumiphore, thereby improving color over angle emission and reduce the need for an additional adhesion interface on the LED. The PiG cover structure can be molded or pressed during a green sheet lamination and sintering process to create the 3D shape. In other embodiments, a PiG structure can be machined into a desired shape.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AIGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AIGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

The active LED structure may be grown on a growth substrate that can include many materials, such as sapphire, SiC, aluminum nitride (AIN), GaN, with a suitable substrate being a 4H polytype of SiC, although other SiC polytypes can also be used including 3C, 6H, and 15R polytypes. SiC has certain advantages, such as a closer crystal lattice match to Group III nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including being lower cost, having established manufacturing processes, and having good light transmissive optical properties.

Different embodiments of the active LED structure can emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example, peak wavelengths primarily in a range from 400 nm to 700 nm.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denoted with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 750 nm to 1100 nm, or more.

The LED chip can also be covered with one or more lumiphoric or other conversion materials, such as phosphors, such that at least some of the light from the LED chip is absorbed by the one or more phosphors and is converted to one or more different wavelength spectra according to the characteristic emission from the one or more phosphors. In some embodiments, the combination of the LED chip and the one or more phosphors emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. Lumiphoric materials as described herein may be or include one or more of a phosphor, a scintillator, a lumiphoric ink, a quantum dot material, a day glow tape, and the like. In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. In some embodiments, one or more phosphors may include yellow phosphor (e.g., YAG:Ce), green phosphor (e.g., LuAg:Ce), and red phosphor (e.g., Ca_{i-x-y}SrₓEu_{y}AlSiN₃) and combinations thereof. One or more lumiphoric materials may be provided on one or more portions of an LED chip and/or a submount in various configurations. In certain embodiments, the loading percentage of one or more lumiphoric materials may be varied relative to one or more outer surfaces of an LED chip. In certain embodiments, one or more lumiphoric materials may be patterned to include one or more stripes, dots, curves, or polygonal shapes. In certain embodiments, multiple lumiphoric materials may be arranged in different discrete regions or discrete layers relative to an LED chip.

Aspects of the present disclosure are provided that include optical arrangements for cover structures of LED packages for improving or otherwise tailoring emission characteristics. Such cover structures may include hard and mechanically robust structures that are positioned over one or more LED chips within an LED package. A cover structure may be configured to provide protection from environmental exposure to underlying portions of an LED package, thereby providing a more robust LED package that is well suited for applications that require high power with increased light intensity, contrast, and reliability, such as interior and exterior automotive applications. Cover structures may comprise host materials such as glass or ceramics that provide mechanically robust structures for environmental protection. Such cover structures may be fabricated by providing sheets of glass frit or ceramic precursor materials, pressing the sheets into planar shapes, and firing or sintering to form hardened structures that can be cut or separated. The resulting cover structure may be referred to as a glass plate or a ceramic plate. When lumiphoric materials, such as phosphors, are included in the glass frit or ceramic precursor materials, the resulting cover structures may be referred to as phosphor in glass (PiG) plates or ceramic phosphor plates. In an embodiment, a transparent ceramic cover structure could be sprayed with a phosphor and silicone mixture to generate a remote phosphor with improved emission characteristics. Conventional phosphor can tend to exhibit non-uniformity of emissions due to poor color over angle for light that is converted. It is to be appreciated herein that when a 3D shaped PiG cover structure or PiG cover structure is referred to, that in different embodiments, the cover structure could be a transparent ceramic cover structure.

The conventional plates have traditionally been planar, and have had at least several drawbacks. The first drawback is that the planar plates have been bonded to the LED chips using an adhesive layer and the adhesive layer can absorb at least some of the light emitted by the LED chip thus reducing the overall transmission efficiency. Another drawback is that a substantial portion of the light incident on the planar plates is at an angle such that reflection and refraction both reduce the transmission efficiency and impair the color over angle emission of the LED device. The 3D shaped PiG cover structure disclosed herein overcomes these drawbacks.

The 3D shaped PiG is also an improvement over 3D shaped plastic shells that may have phosphor embedded in the plastic shell. With the phosphor embedded in glass, and not plastic, there are index of refraction improvements that improve color over angle emissions. Additionally, glass has improved thermal characteristics relative to plastic, and can handle high and low temperatures without becoming brittle. Furthermore, glass does not discolor over time due to ultraviolet radiation or other gases as does plastic. Previously shaping the glass in the desired shape was difficult, but the methods of fabrication disclosed herein by heating and pressing green sheets have overcome the challenges of using PiGs.

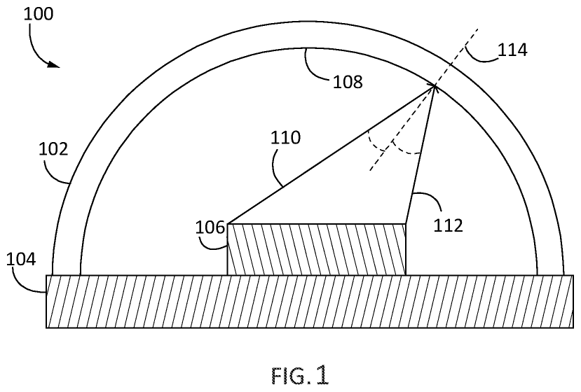

FIG. 1 illustrates an exemplary embodiment of a light emitting diode (LED) package 100 with a 3D shaped phosphor in glass, or transparent ceramic cover structure 102. according to one or more aspects of the present disclosure.

In an embodiment, the PiG cover structure 102 can form the LED package 100 along with a submount 104, and LED chip 106 mounted to the submount 104. In an embodiment, the submount 104 can extend beyond the edges of the LED chip 106 and the PiG cover structure 102 can be mounted to the submount 104. It is to be appreciated that the FIG. 1 is not necessarily to scale, and that the extent to which the submount 104 extends beyond the chip 106 may be larger or smaller relative to the size of the submount 104 and/or LED chip 106 in various embodiments. It is also to be appreciated that the LED chip 106 can in some embodiments be an array of LED chips with a single PiG cover structure 102 covering the array of LED chips. In other embodiments, the LED package 100 can include a plurality of PiG cover structures 102 each covering one or more LED chips 106s.

In an embodiment, the PiG cover structure 102 can be a hemispherical dome shape. In other embodiments, the PiG cover structure can take other shapes with curves or facets. In the various embodiments however, the PiG cover structure 102 can be shaped such that light (e.g., 110, and 112) incident on an internal surface 108 of the PiG cover structure 102 forms an acute angle with respect to a normal axis 114 of the internal surface 108 of the PiG cover structure 102.

In an embodiment, the color of the light that exits the PiG cover structure 102 can be more uniform than if the PiG cover structure 102 were flat as the light passes through the PiG cover structure 102 more directly. When light passes through PiG, light that enters at high angles can encounter more phosphor than light that passes through at an acute angle, which can result in yellower emission near the edges of the flat PiG cover structure.

In an embodiment, the 3D shaped PiG cover structure 102 can serve as a remote phosphor lumiphore, which can improve the color over angle emission by ensuring light passes through the PiG cover structure 102 more uniformly. Additionally, by mounting the PiG cover structure 102 to the submount 104, the light (e.g., 110 and 112) does not pass through an adhesive layer that would have attached the PiG cover structure to the LED chip. The adhesive layer can block some of the light, and so having the PiG cover structure 102 be mounted to the submount 104, transmission efficiency is increased by removing the adhesive layer. In another embodiment, by having the PiG cover structure 102 be at a distance from the LED chip 106 and not touching the LED chip 106, the PiG cover structure 102 is thermally insulated to a degree, and is cooler than the PiG cover structure 102 would be if it were in contact with the LED chip 106. Since transmission efficiency decreases at increased temperatures, the transmission efficiency remains high for PiG cover structure 102.

In an embodiment, the 3D shaped PiG cover structure 102 can be used in applications such as bulbs where a large emission angle is desired, such as bulbs with a 180 ° emission range. In other embodiments, the PiG cover structure 102 can be tuned to help control not color vs angle emission but also intensity vs angle emission, where a desired intensity at predefined angles can be configured.

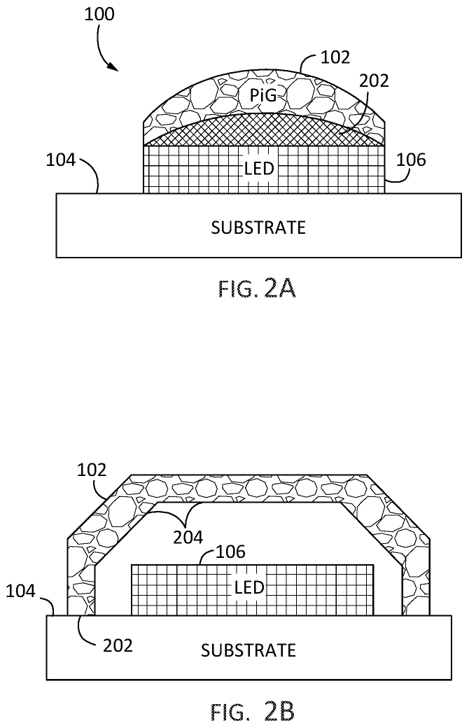

FIGS. 2A and 2B illustrate exemplary embodiments of how a 3D shaped PiG cover structure 102 can be mounted to an LED package 100 according to one or more aspects of the present disclosure.

In FIG. 2A, the PiG cover structure 102 can be shaped into a curved shape and mounted in a traditional manner to the top of an LED chip 106 by an adhesive layer 202. In this embodiment, some of the advantages of the 3D shaped PiG cover structure 102 remain, with the light from the LED chip 106 passing through the PiG cover structure 102 more directly, (e.g., at more acute angles with respect to a normal axis 114 of the PiG cover structure 102) which can lead to decreased reflection, and more uniform color over angle emissions.

In the embodiment in FIG. 2B, the PiG cover structure 102 can be mounted to the substrate 104 at portions of the substrate 104 that are adjacent or laterally spaced from the LED chip 106. The cover structure 102 can be mounted to the substrate 104 at such locations via the adhesive layer 202 as shown in FIG. 1. Furthermore, as shown in FIG. 2B, the shape of the PiG cover structure 102 can be a shape other than a hemispherical dome. In the embodiment in FIG. 2B, the PiG cover structure 102 can have a plurality of facets 204 that can be configured to improve transmission efficiency and color over angle emissions.

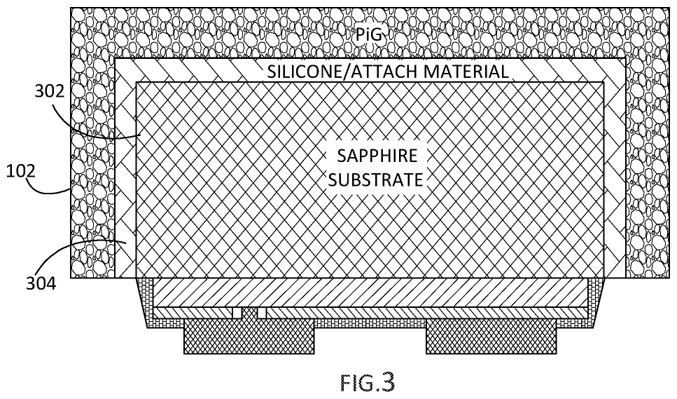

FIG. 3 illustrates another exemplary embodiment of how a 3D shaped phosphor in glass cover structure can be mounted to an LED package according to one or more aspects of the present disclosure. A 3D pressed PiG cover structure 102 can be formed to cover the substrate 302 of a flip chip LED such that the not only is the top surface of the sapphire substrate 302 covered by the PiG cover structure 102, but the side walls of the substrate 302 are also covered so as to provide a more uniform light emission at all emission angles. The PiG cover structure 102 can be mounted to the substrate 302 by a silicone or adhesive layer 304. In an embodiment, the substrate 302 could be sapphire or any other material suitable for growth substrates as described above.

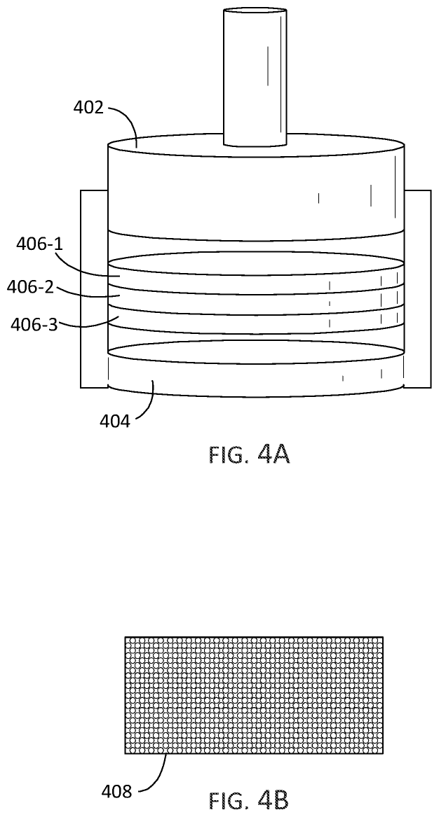

FIGS. 4A and 4B illustrate an exemplary fabrication process for forming cover structures with varying optical arrangements according to principles of the present disclosure. FIG. 4A illustrates a cross-sectional view at a first fabrication step where multiple sheets 406-1, 406-2, and 406-3 of precursor materials are provided that have different optical arrangements from one another. In certain embodiments, a precursor material for a glass plate may comprise glass frit and a corresponding binder, and a precursor material for a ceramic plate may comprise ceramic materials and a corresponding binder. The precursor materials may typically be formed as a slurry that is dried to form the corresponding sheets 406-1, 406-2, and 406-3. As described herein, the sheets 406-1, 406-2, and 406-3 may sometimes be referred to as green sheets that refer to composite sheets before firing. By way of example, each of the sheets 406-1, 406-2, and 406-3 may comprise an optical material, such as a lumiphoric material (e.g., phosphor). In still further embodiments, the lumiphoric materials may be provided with uniform or graded loading amounts or quantities within the precursor material, such as progressively decreasing quantities of lumiphoric material from the first sheet 406-1 toward the last sheet 406-3. Depending on the desired emission characteristics, the loading amounts of lumiphoric materials may be provided in other arrangements, including progressively increasing amounts from the first sheet 406-1 toward the last sheet 406-3, or distributions increasing and decreasing from the first sheet 406-1 toward the last sheet 406-3. While FIG. 4A is described in the context of lumiphoric materials, the sheets 406-1, 406-2, and 406-3 may include one or more combinations with other optical arrangements of optical materials, including arrangements of materials with different indexes of refraction, light-scattering materials, and light-diffusing materials separately or in combination with lumiphoric materials. Additionally, while FIG. 4A is illustrated with three sheets 406-1, 406-2, and 406-3, the concepts disclosed may be applicable to any number of sheets. In certain embodiments, the number of sheets 406-1, 406-2, and 406-3 comprises a range from 2 to 10 sheets, or a range from 2 to 8 sheets, or a range from 2 to 6 sheets. Thickness ranges for the sheets 406-1, 406-2, and 406-3 may be tailored to particular applications, with some ranges being provided in a range from 20 microns (μm) to 500 μm, or in a range from 20 μm to 300 μm, or in a range from 50 μm to 250 μm, or in a range from 100 μm to 200 μm.

FIG. 4A further illustrates where the multiple sheets 406-1, 406-2, and 406-3 are pressed together by a press 402 and 404 and fired to form a PiG structure 408 as depicted in FIG. 4B, which is a cross-sectional diagram of the PiG structure 408 which can have a rounded or oval cylindrical shape. During firing, binder materials of the sheets 406-1, 406-2, and 406-3 are reduced and/or removed, thereby providing the PiG structure 408 as a rigid structure with the various sublayers 406-1, 406-2, and 406-3 having different optical characteristics. As binder materials are removed during firing, the PiG structure 408 may comprise a compressed thickness relative to a sum of the respective sheets 406-1, 406-2, and 406-3 before pressing and firing. By way of example, if each of the four sheets 406-1, 406-2, and 406-3 was provided with an initial thickness of 200 μm for a total of 800 μm when stacked, the resulting cover structure 16 may have a final thickness in a range from 400 μm to 500 μm after firing. After firing, the PiG structure 408 may optionally be subjected to a removal process, such as polishing, that can reduce the thickness of the cover structure 16 further to a targeted range. In certain embodiments, thicknesses of PiG structure 408 intended for LED package applications, may have a final thickness in a range from 25 μm to 500 μm, or in a range from 25 μm to 300 μm, or in a range from 100 μm to 250 μm. The resulting PiG structure 408 can be used in embodiments where the PiG cover structure 102 is made by machining the PiG structure 408 into a desired shape.

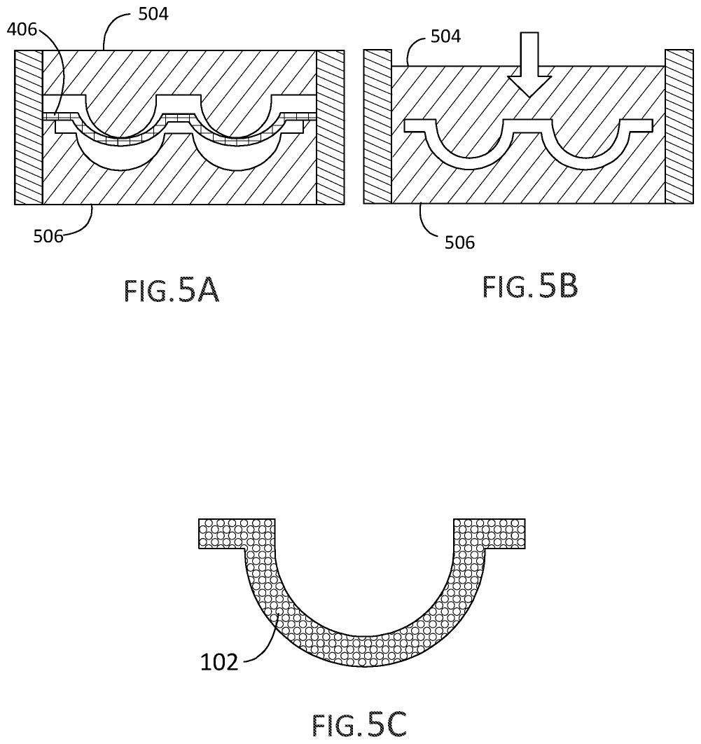

In an embodiment depicted in FIGS. 5A-C, the shaping of the PiG cover structure 102 can be done while pressing and baking and/or sintering the green sheets 406.

In an embodiment, the green sheets 406 (e.g., 406-1, 406-2, and 406-3) can be placed between a shaped press 504 and mold 506 in FIG. 5A. While in the press/mold, and before force is applied to the press 504 or mold 506, the green sheets 406 can be heated to a temperature above the glass transition temperature but below the decomposition point of the phosphor. This heating can be done slowly to avoid thermal shock to the PiG.

Once the PiG has reached the predetermined temperature, the press 504 can be pressed into the mold 506 as shown in FIG. 5B to shape the green sheets 406 into the desired shape. In an embodiment, the press 504 and the mold 506 can also be heated to the predetermined temperature to avoid temperature shock. During the cooling phase there could be some slight shrinkage of the final PiG cover structure 102.

In an alternative embodiment, the heating and pressing performed in FIGS. 5A-5C can be done to the PiG structure 408 after the PiG structure 408 is baked and sintered. The heating performed in FIG. 5A can be sufficient to mold the PiG structure 408 post sintering.

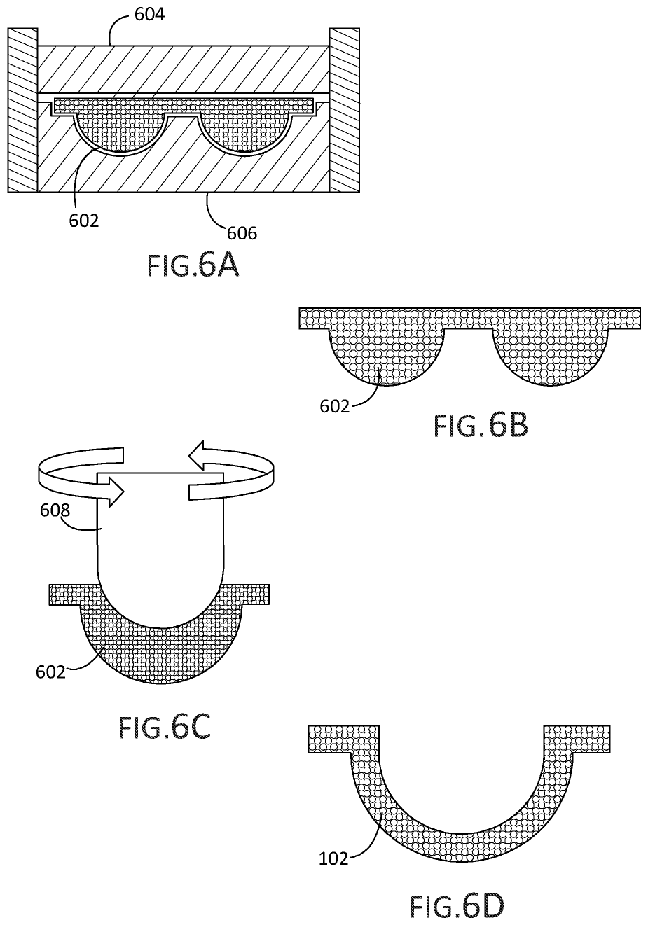

In FIGS. 6A-6D, illustrated is an alternative embodiment where the green sheets 406 are both pressed and machined into the final PiG cover structure 102.

The press 604 in FIG. 6A can be flat, whereas the mold 606 can be shaped similarly to mold 504. The green sheets are pressed while being sintered between press 604 and mold 606 resulting in an intermediate PiG structure 602 as shown in FIG. 6B. As in FIG. 5B and FIG. 6A, the green sheets can form a large sheet that is pressed by a press and mold that has multiple shapes. The resulting intermediate PiG structure 602 can comprise a plurality of shapes, each of which can form separate PiG structures 102 after being singulated, or separated from each other. In certain embodiments, singulation may involve sub-dividing the intermediate PiG structure 602 into a number of smaller cover structures and vertical separation lines can be superimposed where the intermediate PiG structure 602 may be divided. The singulation process may comprise dicing with one or more of a saw blade and a laser along the separation lines. In this manner, the lateral dimensions of the PiG cover structure 102 can be tailored to a particular LED package.

Once the intermediate PiG structure 602 has been singulated, a machining tool 608 can machine the intermediate PiG structure 602 into a hemispherical dome in FIG. 6C until the PiG cover structure 102 is completed after machining and polishing, as shown in FIG. 6D. In an embodiment, the machining tool 608 can be automatically controlled by a Computer Numerical Control (CNC) controller.

In an embodiment, the heating and pressing performed in FIGS. 5A-5C and in FIGS. 6A-6D can be done to the PiG structure 408 after the PiG structure 408 is baked and sintered. Therefore, instead of placing the green sheets 406 into the molds, the PiG structure 408 can be placed in the molds heated and then pressed into the desired cover structure shapes.

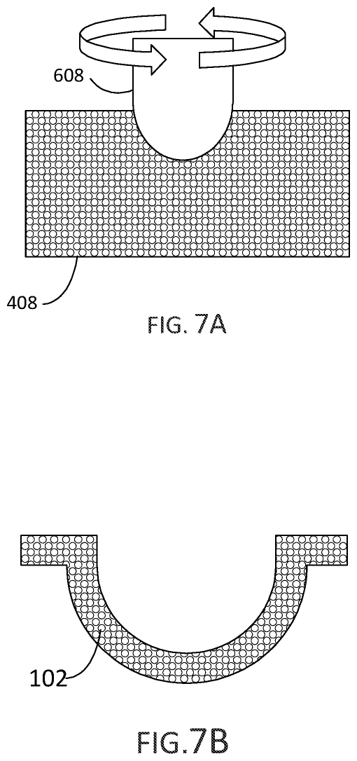

Alternatively, as shown in FIGS. 7A and 7D, the PiG structure 408 that was created as shown in FIG. 4, can be directly machined by CNC controlled machine tool 608 into the desired PiG cover structure shape 102 without heating and pressing/molding.

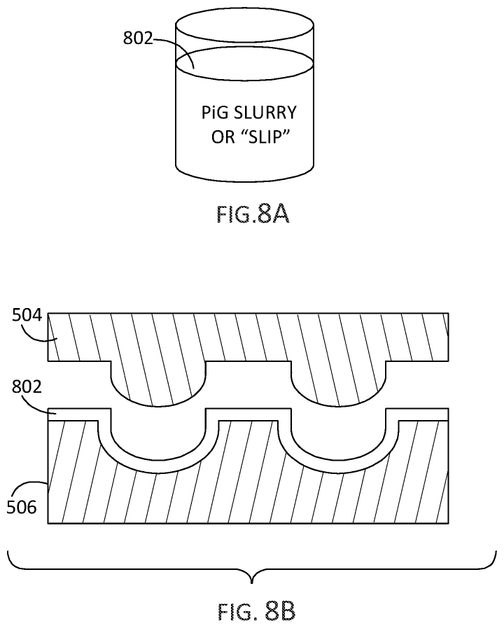

FIGS. 8A-8B illustrate an embodiment where the PiG slurry 802 that is a ceramic slurry with binders and other additives can be used in a slip casting system to form complex shapes after water in the slurry 802 drains out via the porous mold 506. After the water drains, the slurry 802 can be sintered directly to form the intermediate PiG structure which can then be singulated to form PiG cover structures 102, or the slurry 802 can optionally be pressed by press 504 with a hot isostatic press, and then sintered and singulated.

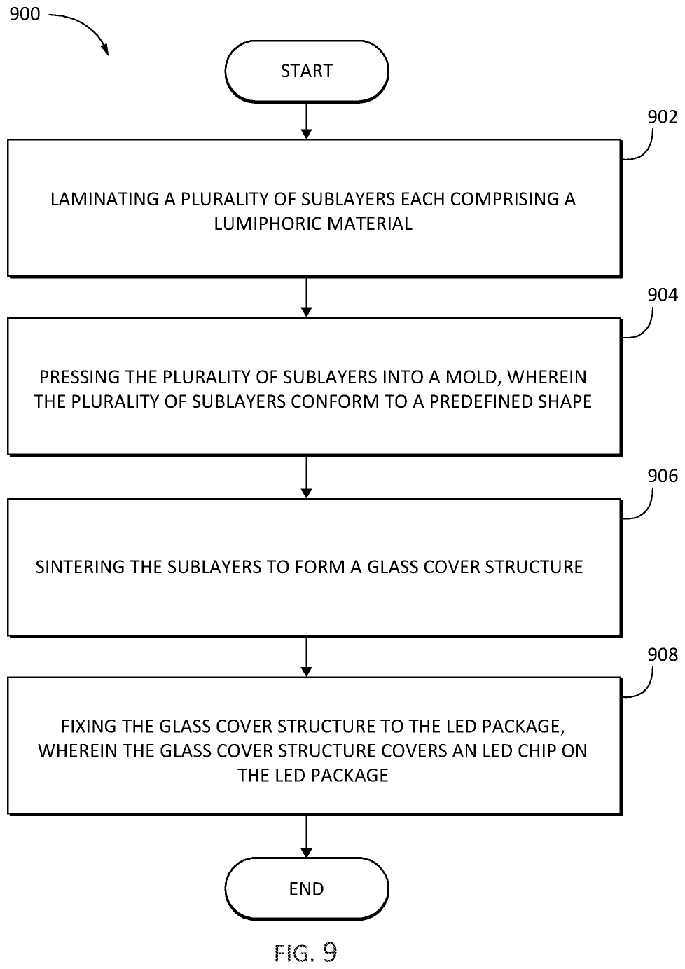

FIG. 9 illustrates an exemplary flowchart of a method 900 for fabricating a 3D shaped PiG cover structure (e.g., PiG cover structure 102) according to one or more aspects of the present disclosure.

The method can begin at step 902 where the method includes laminating a plurality of sublayers each comprising a lumiphoric material. In one or more embodiments, the lumiphoric material can be phosphor.

At step 904, the method includes pressing the plurality of sublayers into a mold, wherein the plurality of sublayers conform to a predefined shape. In an embodiment, the predefined shape can be a hemispherical dome. In other embodiments, the predefined shape can have a plurality of planar facets. The predefined shape can be such that when light is incident on an internal surface of the glass cover structure the light is at an acute angle relative to an axis normal to the internal surface of the shape.

At step 906, the method includes sintering the sublayers to form a glass cover structure.

At step 908, the method includes fixing the glass cover structure to the LED package, wherein the glass cover structure covers an LED chip on the LED package. The glass cover structure can be mounted to a submount in some embodiments, or directly to the LED chip of the LED package in other embodiments. In an embodiment where the glass cover structure is mounted to the submount, the glass cover structure can serve as a remote phosphor lumiphore, thereby improving color over angle emission and reducing the need for an additional adhesion interface on the LED.

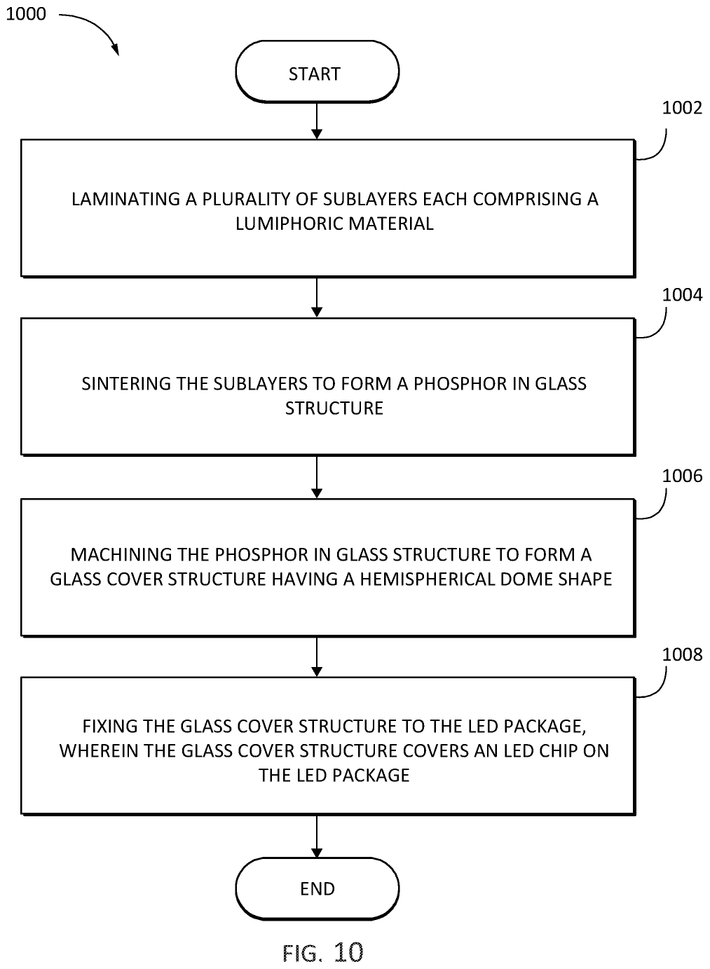

FIG. 10 illustrates an exemplary flowchart of a method 1000 for fabricating a 3D shaped PiG cover structure (e.g., PiG cover structure 102) according to one or more aspects of the present disclosure.

The method can begin at step 1002 where the method includes laminating a plurality of sublayers each comprising a lumiphoric material. In one or more embodiments, the lumiphoric material can be phosphor

At step 1004, the method includes sintering the sublayers to form a phosphor in glass structure.

At step 1006, the method includes machining the phosphor in glass structure to form a glass cover structure having a hemispherical dome shape. In an embodiment, the hemispherical dome shape can be such that when light is incident on an internal surface of the glass cover structure the light is at an acute angle relative to an axis normal to the internal surface of the glass cover structure.

At step 1008, the method includes fixing the glass cover structure to the LED package, wherein the glass cover structure covers an LED chip on the LED package. The glass cover structure can be mounted to a submount in some embodiments, or directly to the LED chip of the LED package in other embodiments. In an embodiment where the glass cover structure is mounted to the submount, the glass cover structure can serve as a remote phosphor lumiphore, thereby improving color over angle emission and reducing the need for an additional adhesion interface on the LED.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light emitting diode (LED) package, comprising:
a submount;
an LED chip on the submount; and
a cover structure embedded with a lumiphoric material, wherein an internal surface of the cover structure is non-planar, and at least a portion of the glass cover structure is not in contact with the LED chip.

2. The LED package of claim 1, wherein the cover structure is mounted to the submount.

3. The LED package of claim 1, wherein an entirety of the cover structure is not in contact with the LED chip.

4. The LED package of claim 1, wherein the cover structure forms a hemispherical dome.

5. The LED package of claim 1, wherein an internal surface of the cover structure is curved.

6. The LED package of claim 1, wherein an internal surface of the cover structure comprises a plurality of facets.

7. The LED package of claim 1, wherein a light incident on an internal surface of the glass cover structure is at an acute angle relative to an axis normal to the internal surface of the cover structure.

8. The LED package of claim 1, wherein the lumiphoric material is phosphor.

9. The LED package of claim 1, wherein the cover structure is at least one of glass or ceramic.

10. A method of forming a light emitting diode (LED) package comprising a glass cover structure, the method comprising:
laminating a plurality of sublayers, each embedded with a lumiphoric material;
pressing the plurality of sublayers into a mold, wherein the plurality of sublayers conform to a predefined shape;
baking or sintering the sublayers to form a glass cover structure; and
fixing the glass cover structure to the LED package, wherein the glass cover structure covers an LED chip on the LED package.

11. The method of claim 10, wherein the predefined shape is a hemispherical dome.

12. The method of claim 10, wherein the predefined shape is a hemisphere, and wherein the method further comprises:
machining an inside of the hemisphere to form a hemispherical dome.

13. The method of claim 10, wherein the fixing further comprises mounting the glass cover structure to a submount of the LED package.

14. The method of claim 13, wherein the entirety of the glass cover structure is not in contact with the LED chip.

15. The method of claim 10, wherein the fixing further comprises mounting the glass cover structure to the LED chip of the LED package.

16. The method of claim 10, wherein the pressing further comprises pressing the plurality of sublayers into a plurality of molds.

17. The method of claim 16, further comprising baking or sintering the sublayers to form a plurality of glass cover structures; and
separating the plurality of glass cover structures from each other.

18. The method of claim 10, wherein the lumiphoric material is phosphor.

19. The method of claim 10, further comprising:
heating the plurality of sublayers during the pressing to a predefined temperature.

20. A method of forming a light emitting diode (LED) package comprising a glass cover structure, the method comprising:
laminating a plurality of sublayers, each embedded with a lumiphoric material;
baking or sintering the sublayers to form a phosphor in glass structure;
machining the phosphor in glass structure to form a glass cover structure having a hemispherical dome shape; and
fixing the glass cover structure to the LED package, wherein the glass cover structure covers an LED chip on the LED package.
